(19) United States
(12) Patent Application Publication
(10) Pub. No.: US 2022/0085147 A1
(43) Pub. Date: Mar. 17, 2022

(54) DIELECTRIC THIN FILM ELEMENT AND ELECTRONIC CIRCUIT DEVICE

(71) Applicant: TDK CORPORATION, Tokyo (JP)

(72) Inventors: Yasunori HARADA, Tokyo (JP); Daiki ISHII, Tokyo (JP); Yoshihiko YANO, Tokyo (JP)

(73) Assignee: TDK CORPORATION, Tokyo (JP)

(21) Appl. No.: 17/470,338

(22) Filed: Sep. 9, 2021

(30) Foreign Application Priority Data
Sep. 16, 2020 (JP) 2020-155341

(51) Int. Cl. H01L 49/02

(52) U.S. Cl. CPC H01L 28/60

(57) ABSTRACT

A dielectric thin film element including a first electrode layer, a dielectric layer, and a second electrode layer located in this order from a substrate side. A relationship of 0.75≤Rsk1≤5.0 is satisfied, in which skewness of a roughness curve of the first electrode layer on the dielectric layer side is set as Rsk1.

### BACKGROUND OF THE INVENTION

The present invention relates to a dielectric thin film element and an electronic circuit device.

Patent Document 1 describes an invention relating to a dielectric element. An average value of arithmetic mean roughness at an interface between a metal layer and a dielectric layer and the thickness of the dielectric layer are set within specific ranges to suppress a leakage current.

[Patent Document 1] JP Patent Application Laid Open No. 2007-329190

### BRIEF SUMMARY OF INVENTION

An object of the present invention is to provide a dielectric thin film element having a high breakdown voltage.

The dielectric thin film element according to an aspect of the present invention is a dielectric thin film element including a first electrode layer, a dielectric layer, and a second electrode layer located in this order from a substrate side, wherein

a relationship of 0.75≤Rsk1≤5.0 is satisfied, in which

skewness of a roughness curve of the first electrode layer on the dielectric layer side is set as Rsk1.

A total amount of C, P, S, and Se in the dielectric layer may be less than 25 ppm.

Mohs hardness of the first electrode layer may be 4 or more.

A relationship of −1.0<Rsk2≤5.0 may be satisfied, in which

skewness of a roughness curve of the second electrode layer on the dielectric layer side is set as Rsk2.

An intermediate layer having a thickness of 1 nm or more may be provided between the first electrode layer and the dielectric layer.

The first electrode layer and the dielectric layer may be in contact with each other.

The dielectric layer and the second electrode layer may be in contact with each other.

The electronic circuit substrate according to another aspect of the present invention is an electronic circuit substrate including the dielectric thin film element.

The electronic circuit device according to still another aspect of the present invention is an electronic circuit device including the dielectric thin film element and a substrate on which the dielectric thin film element is formed.

### BRIEF DESCRIPTION OF DRAWINGS

FIG. 1 is a schematic view of a thin film capacitor according to an embodiment of the present invention.

FIG. 2 is an example of a roughness curve in the case of Rsk<0.

FIG. 3 is an example of a roughness curve in the case of Rsk>0.

FIG. 4 is a schematic view of a result of spectral analysis of the roughness curve in FIG. 2.

FIG. 5 is a schematic view of a result of spectral analysis of the roughness curve in FIG. 3.

### DETAILED DESCRIPTION OF INVENTION

Hereinafter, the present invention will be described on the basis of an embodiment.

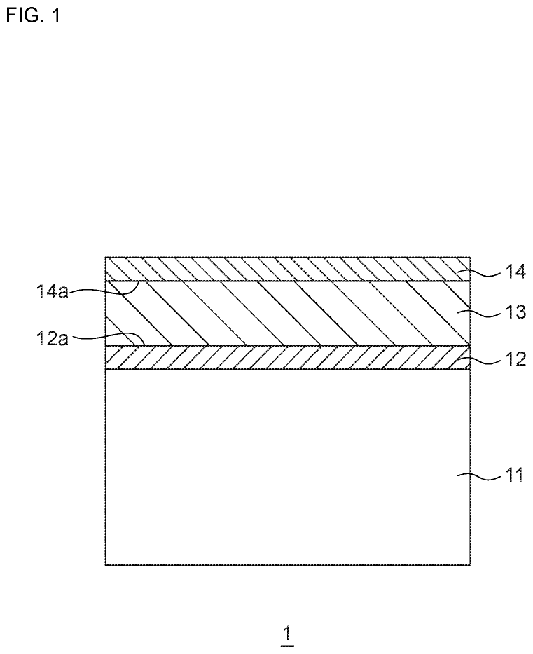

FIG. 1 is a schematic view of a thin film capacitor according to this embodiment. In a thin film capacitor 1 illustrated in FIG. 1, a first electrode layer 12, a dielectric layer 13, and a second electrode layer 14 are sequentially formed on a substrate 11, thereby constituting the thin film capacitor 1.

A material of the substrate 11 is not particularly limited. In the case of forming the first electrode layer 12 of which a material is different from that of the substrate 11 on the substrate 11, for example, as the substrate 11, an Si single crystal substrate, or an LTCC substrate can be used.

A material of the first electrode layer 12 and the second electrode layer 14 is not particularly limited as long as the layers function as an electrode. Examples of the material include Pt, Ni, Ir, Al, Cu, Ag, Pd, and the like. In addition, the material of the electrode may be an alloy containing Pt, Ni, Ir, Al, Cu, Ag and Pd. For example, an Ag—Pd alloy, and the like can be exemplified. The material of the first electrode layer 12 and the material of the second electrode layer 14 may be the same as or different from each other.

A total thickness of the substrate 11 and the first electrode layer 12 is not particularly limited. For example, the total thickness may be 0.01 to 1 mm.

A sheet of metal foil may serve as the substrate 11 and the first electrode layer 12. In this case, a boundary between the substrate 11 and the first electrode layer 12 may not be confirmed.

In a case where the substrate 11 and the first electrode layer 12 are formed from materials different from each other, the thickness of the first electrode layer 12 is not particularly limited. For example, the thickness may be 0.1 to 1 μm.

The thickness of the second electrode layer 14 is not particularly limited. For example, the thickness may be 0.1 to 1 μm.

The thickness of the dielectric layer 13 is not particularly limited. For example, the thickness may be 0.1 to 1 μm.

A material of the dielectric layer 13 is not particularly limited. Examples of the material include a perovskite-type oxide, a perovskite-type oxynitride, a composite perovskite-type oxide, a composite perovskite-type oxynitride, and the like.

For example, the perovskite-type oxide can be expressed by a composition formula ABO₃ (atomic number ratio). For example, the perovskite-type oxynitride can be expressed by a composition formula ABO_{3-δ}N_{δ}(0<δ≤1) (atomic number ratio).

The kind of A and B is not particularly limited, A may be an element that mainly occupies an A-site of a perovskite structure, and B may be an element that mainly occupies a B-site of the perovskite structure. For example, A may be one or more kinds of elements selected from Sr, Ba, Ca, La, Ce, Pr, Nd, and Na. B may be one or more kinds of elements selected from Ta, Nb, Ti, and W. The composite perovskite-type oxide is a perovskite-type oxide in which A and/or B are composed of two or more kinds of elements. The composite perovskite-type oxynitride is a perovskite-type oxynitride in which A and/or B are composed of two or more kinds of elements.

A total amount of C, P, S, and Se in the dielectric layer 13 is preferably less than 25 ppm. C, P, S, and Se are contained as impurities. In addition, C, P, S, and Se may react with elements contained in the dielectric layer 13, particularly with elements of Group 2 (Ba, Sr, Ca, and the like), and carriers are generated through the reaction. When the carriers are generated in the dielectric layer 13, breakdown strength of the dielectric layer 13 decreases, and thus a breakdown voltage of the dielectric layer 13 decreases. Accordingly, in a case where the total amount of C, P, S, and Se is less than 25 ppm, generation of the carriers is likely to be suppressed, the breakdown strength of the dielectric layer 13 is likely to be improved, and the breakdown voltage of the dielectric layer 13 is likely to be improved.

An intermediate layer may exist between the first electrode layer 12 and the dielectric layer 13. A kind of the intermediate layer is not particularly limited. A known intermediate layer is also possible as the layer between the electrode layer and the dielectric layer. The thickness of the intermediate layer is set to 1 nm or more. In this embodiment, an intermediate layer having a thickness of less than 1 nm is regarded as non-existence, and in a case where the intermediate layer does not exist, it is regarded that the first electrode layer 12 and the dielectric layer 13 are in contact with each other. An upper limit of the thickness of the intermediate layer between the first electrode layer 12 and the dielectric layer 13 is not particularly limited. For example, the thickness may be 5 nm or less.

An intermediate layer may also exist between the second electrode layer 14 and the dielectric layer 13 as between the first electrode layer 12 and the dielectric layer 13. The second electrode layer 14 and the dielectric layer 13 may be in contact with each other without the intermediate layer. An upper limit of the thickness of the intermediate layer between the second electrode layer 14 and the dielectric layer 13 is not particularly limited. For example, the thickness may be 5 nm or less.

The thin film capacitor 1 according to this embodiment has a characteristic in surface roughness of an interface 12a of the first electrode layer 12 on the dielectric layer 13 side. Specifically, a relationship of 0.75≤Rsk1≤5.0 is satisfied, in which skewness of a roughness curve in the interface 12a of the first electrode layer 12 is set as Rsk1.

Typically, the skewness (Rsk) of the roughness curve is expressed by the following expression as defined in JIS B 0601:2013. lr represents a sampling length, and Rq represents a root mean square deviation. Note that, the skewness is a parameter representing a deviation of the distribution of unevenness.

$$R s k = \frac{1}{{Rq}^{3}} [ \frac{1}{lr} {\int }_{0}^{lr} {R}^{3} ( x ) dx ] \qquad [ Mathematical Formula 1 ]$$

The root mean square deviation Rq is expressed by the following expression as defined in JIS B 0601:2013. l represents a sampling length, and in measurement of Rsk, 1 equals to lr.

$${R}_{q} = \sqrt{\frac{1}{l} {\int }_{0}^{l} {R}^{2} ( x ) dx} \qquad [ Mathematical Formula 2 ]$$

A method of measuring the skewness of the roughness curve of the first electrode layer 12 on the dielectric layer 13 side is not particularly limited. For example, the roughness curve of the first electrode layer 12 on the dielectric layer 13 side can be obtained by cutting the thin film capacitor 1 along a stacking direction, and by observing an obtained cross-section with a SEM. In addition, the skewness Rsk can be calculated from the obtained roughness curve. A SEM observation magnification is not particularly limited, and may be a magnification capable of observing the roughness curve. In addition, the sampling length 1 may be a length sufficient for measuring Rsk.

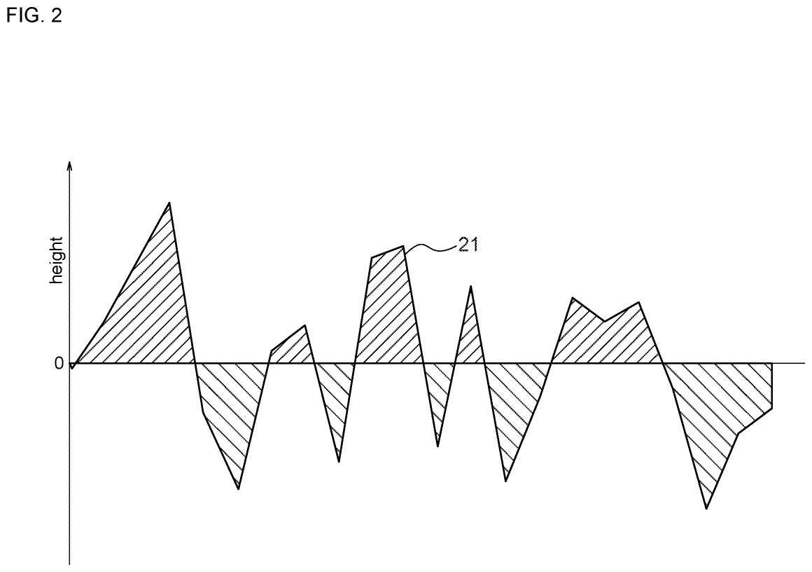

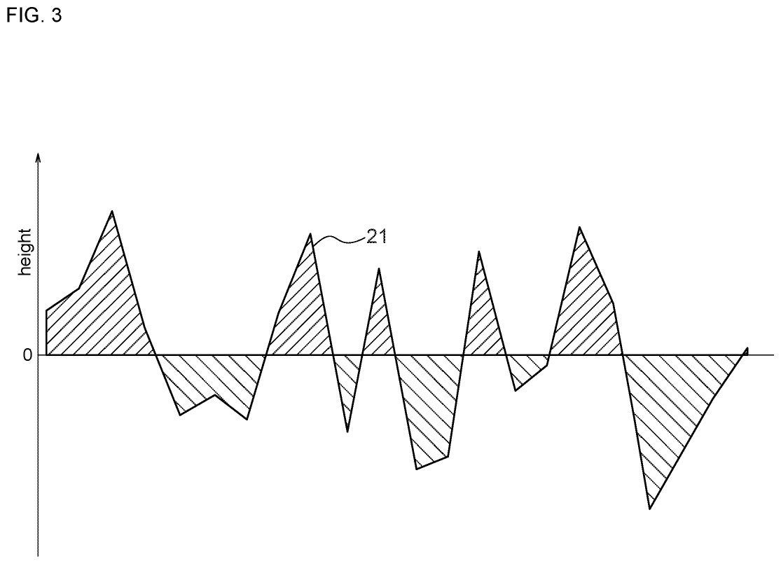

An example of a roughness curve 21 in the case of Rsk<0 is illustrated in FIG. 2, and an example of a roughness curve 21 in the case of Rsk>0 is illustrated in FIG. 3. In the roughness curve 21 in FIG. 2 and the roughness curve 21 in FIG. 3, arithmetic mean roughness Ra and maximum height roughness Rz are the same as each case. In FIG. 2 and FIG. 3, a portion higher than an average line and a portion lower than the average line can be distinguished. Fewer steep recessions exist in the roughness curve in FIG. 3 in the case of Rsk>0 in comparison to the roughness curve in FIG. 2 in the case of Rsk<0.

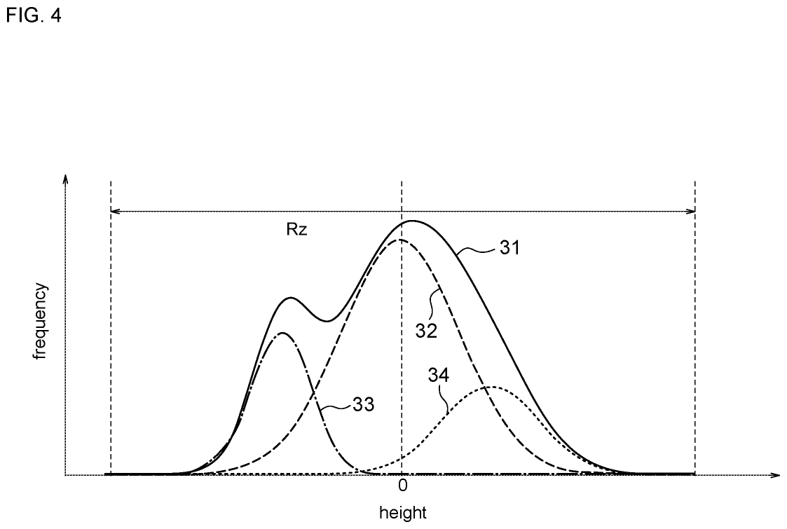

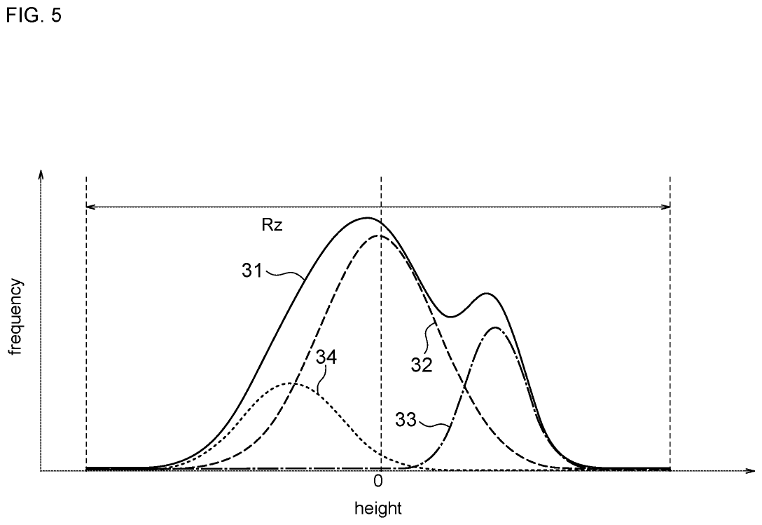

In addition, FIG. 4 is a schematic view of a result of spectral analysis of the roughness curve 21 in FIG. 2, and FIG. 5 is a schematic view of a result of spectral analysis of the roughness curve 21 in FIG. 3. In FIG. 4 and FIG. 5, in addition to a roughness spectrum 31 obtained by spectrally converting the roughness curve 21, a first spectral component 32, a second spectral component 33, and a third spectral component 34 obtained by spectrally resolving the roughness spectrum 31 are described.

When comparing FIG. 4 and FIG. 5 with each other, a great difference is not present in the first spectral component 32. However, a great difference is present in the second spectral component 33. A peak of the second spectral component 33 exists at a negative position in FIG. 4, whereas a peak of the second spectral component 33 exists at a positive position in FIG. 5. From this point, it can be seen that in the case of Rsk>0, steep recessions are fewer in comparison to the case of Rsk<0.

In the case of satisfying a relationship of 0.75≤Rsk1≤5.0, particularly, a relationship of 0.75≤Rsk1, steep recessions on the electrode surface of the first electrode layer 12 on the dielectric layer 13 side decrease. Accordingly, the first electrode layer 12 is coated with the dielectric layer 13 (the intermediate layer in a case where the intermediate layer exists) along the surface of the first electrode layer 12, and gaps between the dielectric layer 13 (the intermediate layer in a case where the intermediate layer exists) and the first electrode layer 12 decrease. As a result, the breakdown voltage becomes high, and the breakdown strength becomes high. Note that, in a case where Rsk1 is more than 5.0, steep convex portions increase in the first electrode layer 12. As a result, the dielectric layer 13 (the intermediate layer in a case where the intermediate layer exists) is less likely to be uniformly coated along the surface of the first electrode layer 12, and thus the breakdown strength of the thin film capacitor 1 is likely to decrease.

The Mohs hardness of the first electrode layer 12 is not particularly limited, but may be 4 or more. As the Mohs hardness becomes greater, the steep recessions are less likely to be generated in a polishing process. In addition, gaps between the surface of the first electrode layer and the dielectric layer 13 (the intermediate layer in a case where the intermediate layer exists) decrease. As a result, Rsk1 is likely to be high. In addition, as the Mohs hardness is lower, Rsk1 is likely to decrease, and thus it is difficult to perform polishing so that Rsk1 is within the above-described range. That is, as the Mohs hardness of the first electrode layer 12 is higher, it is easier to manufacture the thin film capacitor 1 in which Rsk1 is within the above-described range.

In addition, when using the first electrode layer 12 and the second electrode layer 14 in which a work function is large, the breakdown voltage of the thin film capacitor 1 tends to be high. In order to increase the work function of the first electrode layer 12 and the second electrode layer 14, it is preferable to select a material containing Ni, Pt, Ir, Pd, Au, or the like as a material of the first electrode layer 12 and the second electrode layer 14.

Note that, the arithmetic mean roughness and the maximum height roughness which are calculated from the roughness curve of the first electrode layer 12 on the dielectric layer 13 side are not particularly limited. A relationship of 0 nm≤Ra1≤25 nm may be satisfied, in which the arithmetic mean roughness is set as Ra1. A relationship of 50 nm≤Rz1≤2500 nm may be satisfied, in which the maximum height roughness is set as Rz1. When Ra1 is within the above-described range, Rsk1 is likely to be high. When Rz1 is within the above-described range, Rsk1 is likely to be high.

Surface roughness of the interface 14a of the second electrode layer 14 on the dielectric layer 13 side is not particularly limited, but a relationship of −1.0<Rsk2≤5.0 may be satisfied, or −0.9≤Rsk2≤5.0 may be satisfied, in which skewness of a roughness curve of the interface 14a of the second electrode layer 14 on the dielectric layer 13 side is set as Rsk2. As in the first electrode layer 12, in the second electrode layer 14, as Rsk2 is high and steep recessions are fewer on an electrode surface, the breakdown voltage becomes higher, and the breakdown strength becomes high. Note that, in a case where Rsk2 is more than 5.0, gaps between the dielectric layer 13 (the intermediate layer in a case where the intermediate layer exists) and the second electrode layer 14 increase.

Method of Manufacturing Thin Film Capacitor 1

Next, a method of manufacturing the thin film capacitor 1 will be described.

First, the substrate 11 and the first electrode layer 12 are prepared. A method of preparing the substrate 11 and the first electrode layer 12 is not particularly limited. In a case where a sheet of metal foil serves as both the substrate 11 and the first electrode layer 12, the substrate 11 and the first electrode layer 12 are simultaneously prepared. In the case of forming the first electrode layer 12 on the substrate 11, the first electrode layer 12 can be formed by a known method. Examples of the method include a sputtering method and a vapor deposition method.

Next, in order to control Rsk1, a surface treatment may be performed on the first electrode layer 12. A method of the surface treatment is not particularly limited. Examples of the method include a polishing method, a sputtering method, and a reverse sputtering method. In addition, a plurality of methods may be carried out.

In the polishing method, Rsk1 can be controlled by changing a size of abrasive grains, the number of times of polishing, or the like. As the size of the abrasive grains is made smaller, and the number of times of polishing is increased, steep recessions are decreased, and thus Rsk1 can be increased.

In the sputtering method, a thin film that is the first electrode layer 12 is formed on the substrate 11 (may also serve as the first electrode layer 12) by sputtering. The amount of the steep recessions and Rsk1 can be controlled by controlling sputtering conditions, particularly, electric power and a substrate temperature.

In the reverse sputtering method, after forming the first electrode layer 12, plasma etching of the first electrode layer 12 is performed by reverse sputtering. The amount of steep recessions and Rsk1 can be controlled by controlling reverse sputtering conditions, particularly, electric power, a substrate temperature, and etching time.

In the case of forming an intermediate layer on the first electrode layer 12, the intermediate layer is formed at this time. A method of forming the intermediate layer is not particularly limited.

Next, the dielectric layer 13 is formed on the first electrode layer 12 (the intermediate layer in the case of forming the intermediate layer). A method of forming the dielectric layer 13 is not particularly limited. Examples of the method include a vacuum deposition method, a sputtering method, a pulse laser deposition method (PLD method), a metal organic chemical vapor deposition method (MO-CVD), a metal organic decomposition method (MOD), a sol gel method, and a chemical solution deposition method (CSD). In addition, in the case of forming the dielectric layer 13 by the sputtering method, the amount of impurities of the dielectric layer 13 can be controlled by controlling the amount of impurities of a target for film formation. In addition, the amount of impurities can also be controlled by changing the kind of a gas introduced into a chamber, and a mixing ratio of the gas.

Next, in the case of forming an intermediate layer on the dielectric layer 13, the intermediate layer is formed at this time. A method of forming the intermediate layer is not particularly limited.

Next, the second electrode layer 14 is formed on the dielectric layer 13 (the intermediate layer in the case of forming the intermediate layer). The second electrode layer 14 can be formed by a known method. Examples of the method include the sputtering method and the MO-CVD method.

In addition, Rsk2 can be changed by changing formation conditions of the second electrode layer 14. In the case of forming the second electrode layer by the sputtering method, Rsk2 can be increased by changing electric power and a substrate temperature.

Hereinbefore, description has been given of an embodiment of the thin film capacitor that is a kind of the dielectric thin film element of the present invention, but the present invention is not limited to the embodiment at all, and the present invention can be carried out in various aspects in a range not departing from the gist of the present invention.

In the dielectric thin film element of the present invention, the breakdown voltage is high and the breakdown strength is high. Accordingly, the dielectric thin film element of the present invention can be appropriately used for applications required to simultaneously accomplish a low profile, high capacity, and a high withstand voltage. For example, an electronic circuit substrate in which the number of electronic components to be mounted is large and a mounting density is required to be improved is exemplified.

In addition, an electronic circuit device of the present invention includes the dielectric thin film element and a substrate on which the dielectric thin film element is formed. In addition, a sheet of metal foil may serve as both the substrate and an electrode layer on one side of the dielectric thin film element.

### EXAMPLES

Hereinafter, the present invention will be described with reference to more detailed examples, but the present invention is not limited to the examples.

(Experimental Example 1: Sample Numbers 1 to 4)

Ni foil was prepared as a first electrode layer that also serves as a substrate. Note that, Mohs hardness of the first electrode layer was 4 or more. Next, a surface of the Ni foil was ultrasonically cleaned. Next, a surface of the cleaned Ni foil was polished. The surface polishing was performed a plurality of times by using alumina abrasive grains. At the first surface polishing, alumina abrasive grains in which D50 of abrasive grains is 0.5 μm were used. At the second surface polishing, alumina abrasive grains in which D50 of abrasive grains is 0.3 μm were used. At the third surface polishing, alumina abrasive grains in which D50 of abrasive grains is 0.05 μm were used. In Sample Numbers 1 to 3, the surface polishing was performed three times. In Sample Number 4, the surface polishing was performed two times. That is, the surface polishing using the alumina abrasive grains in which D50 of abrasive grains is 0.05 μm was not performed.

As a surface treatment, in Sample Number 1, sputtering was performed with respect to the surface-polished substrate (Ni foil) by a sputtering method. In Sample Number 2, reverse sputtering was performed with respect to the surface-polished substrate (Ni foil) by a reverse sputtering method. In Sample Numbers 3 and 4, neither the sputtering nor the reverse sputtering was performed.

In the sputtering method, a target formed from the same metal (Ni) as in the substrate (Ni foil) and the surface-polished substrate (Ni foil) were provided in a chamber of a film formation device. The target and the polished surface of the substrate (Ni foil) were set to face each other. At this time, a distance between the target and the substrate (Ni foil) was set to 70 mm. Next, the pressure inside the chamber was reduced up to 0.45 Pa while introducing an Ar gas into the chamber. Next, electric power of 500 W was applied to the target to form a film of Ni on the substrate (Ni foil) in a thickness of approximately 500 nm. Note that, a temperature of the substrate (Ni foil) was set to room temperature.

In the reverse sputtering method, a target formed from Ni and the surface-polished Ni foil were provided in the chamber of the film formation device. At this time, the distance between the target and the substrate (Ni foil) was set to 70 mm. Next, the pressure inside the chamber was reduced up to 1.2 Pa while introducing an Ar gas into the chamber. Next, electric power of 500 W was applied to the substrate (Ni foil) to plasma-etch the substrate (Ni foil) by approximately 10 nm. Note that, a temperature of the substrate (Ni foil) was set to room temperature.

Next, a dielectric film was formed on the substrate (Ni foil), thereby forming a dielectric layer. Formation of the dielectric film was performed by a sputtering method. First, BaTiO₃ was prepared as a film formation target. Next, the film formation target formed from BaTiO₃ and the surface-polished substrate (Ni foil) were provided in the chamber of the film formation device. At this time, a distance between the film formation target and the substrate (Ni foil) was set to 50 mm. Next, the pressure inside the chamber was reduced up to 1 Pa while introducing an Ar gas into the chamber. Next, after the substrate (Ni foil) was heated to a temperature of 400° C., electric power of 500 W was applied to the film formation target to form a dielectric film on the substrate (Ni foil) in a thickness of approximately 200 nm, thereby forming a dielectric layer.

Next, the dielectric layer was subjected to a heat treatment at 900° C. for 60 minutes.

Here, a concentration of impurities (a total concentration of C, P, S, and Se) in the dielectric layer after the heat treatment was measured by a fluorescent X-ray analysis. X-rays were generated from an Rh target at a tube voltage of 30 kV to irradiate a surface of the dielectric layer. Fluorescent X-rays generated from the surface of the dielectric layer were detected by a detector through a Ge analyzing crystal. The concentration of impurities in the dielectric layer was quantified from intensity of the detected fluorescent X-rays by a fundamental parameter method. Results are shown in Table 1.

Next, an Ni film was formed on the dielectric layer to form a second electrode layer. Formation of the Ni film was performed by a sputtering method. First, Ni was prepared as a film formation target. Next, the substrate (Ni foil) on which the dielectric layer was formed was provided in the chamber of the film formation device. At this time, a distance between the film formation target and the dielectric layer was set to 70 mm. Next, the pressure inside the chamber was reduced up to 0.45 Pa while introducing an Ar gas into the chamber. Next, after the substrate (Ni foil) was heated to a temperature of 500° C., electric power of 500 W was applied to the film formation target to form an Ni film on the dielectric layer in a thickness of approximately 500 nm so as to form the second electrode layer, thereby preparing the dielectric thin film element.

Various kinds of surface roughness were measured with respect to the first electrode layer of the obtained dielectric thin film element. The dielectric thin film element was cut out along a stacking direction, and an interface between the first electrode layer and the dielectric layer at an obtained cross-section was observed with SEM at a magnification of 80000 times. In the SEM observation, 10 observation visual fields were set to positions different from each other, and SEM images were obtained. With respect to all of ten SEM images, an unevenness profile of an interface was prepared, and the arithmetic mean roughness Ra1 of the first electrode layer, the maximum height roughness Rz1 of the first electrode layer, and the skewness Rsk1 of the first electrode layer were calculated. In addition, the obtained various kinds of surface roughness were averaged. In addition, with respect to the second electrode layer, SEM observation was also performed, and the skewness Rsk2 of the second electrode layer was calculated and averaged. Results are shown in Table 1.

A breakdown voltage of the obtained dielectric thin film element was measured. The breakdown voltage was measured by connecting a digital ultra-high resistance/Microammeter (ADVANTEST R8340) to the first electrode layer and the second electrode layer and by applying a voltage at a step of 5 V/second.

In Table 1, a voltage (unit: V) when resistance value decreases by two digits from an initial resistance value, and a value obtained by dividing the voltage when the resistance value decreases by the thickness of the dielectric layer (unit: MV/cm) are described. VBD(+) is a breakdown voltage when the first electrode layer is set as a negative side and the second electrode layer is set as a positive side, and VBD(−) is a breakdown voltage when the first electrode layer is set as the positive side and the second electrode layer is set as the negative side. In this embodiment, a case where both VBD(+) and VBD(−) are 1.50 MV/cm or more is set as “satisfactory”, a case where VBD(+) and VBD(−) are 3.00 MV/cm or more is set as “more satisfactory”, and a case where VBD(+) and VBD(−) are 3.75 MV/cm or more is set as “most satisfactory”.

(Experimental Example 2: Sample Numbers 5 to 7)

Experimental Example 2 was carried out under the same conditions as in Sample Number 1 of Experimental Example 1 except that the amount of impurities of the film formation target was changed by changing the amount of impurities contained in a raw material of the film formation target so as to change the concentration of impurities in the dielectric layer. Results are shown in Table 1.

(Experimental Example 3: Sample Numbers 9 to 11)

Pt foil was prepared as a first electrode layer also serving as a substrate. Note that, the Mohs hardness of the first electrode layer was 4 or more, and was lower than the Mohs hardness of the first electrode layer in Experimental Example 1. Next, a surface of the Pt foil was ultrasonically cleaned. The surface of the cleaned Pt foil was polished. The surface polishing was performed a plurality of times by using alumina abrasive grains. At the first surface polishing, alumina abrasive grains in which D50 of abrasive grains is 0.5 μm were used. At the second surface polishing, alumina abrasive grains in which D50 of abrasive grains is 0.3 μm were used. At the third surface polishing, alumina abrasive grains in which D50 of abrasive grains is 0.05 μm were used. The surface polishing was performed three times in all samples.

As a surface treatment, in Sample Number 9, sputtering was performed with respect to the surface-polished substrate (Pt foil) by a sputtering method. In Sample Number 10, reverse sputtering was performed with respect to the surface-polished substrate (Pt foil) by a reverse sputtering method. In Sample Number 11, neither the sputtering nor the reverse sputtering was performed.

In the sputtering method, a target formed from the same metal (Pt) as in the substrate (Pt foil) and the surface-polished substrate (Pt foil) were provided in the chamber of the film formation device. The target and the polished surface of the substrate (Pt foil) were set to face each other. At this time, a distance between the target and the substrate (Pt foil) was set to 85 mm. Next, the pressure inside the chamber was reduced up to 2.0 Pa while introducing an Ar gas into the chamber. Next, electric power of 300 W was applied to the target to form a film of Pt on the substrate (Pt foil) in a thickness of approximately 500 nm. Note that, a temperature of the substrate (Pt foil) was set to room temperature.

In the reverse sputtering method, a target formed from Pt and the surface-polished Pt foil were provided in the chamber of the film formation device. At this time, the distance between the target and the substrate (Pt foil) was set to 85 mm. Next, the pressure inside the chamber was reduced up to 2.0 Pa while introducing an Ar gas into the chamber. Next, electric power of 300 W was applied to the substrate (Pt foil) to plasma-etch the substrate (Pt foil) by approximately 5 nm. Note that, a temperature of the substrate (Pt foil) was set to room temperature.

Next, a dielectric film was formed on the substrate (Pt foil), thereby forming a dielectric layer. Formation of the dielectric film was performed by a sputtering method. First, BaTiO₃ was prepared as a film formation target. Next, the film formation target formed from BaTiO₃ and the surface-polished substrate (Pt foil) were provided in the chamber of the film formation device. At this time, a distance between the film formation target and the substrate (Pt foil) was set to 50 mm. Next, the pressure inside the chamber was reduced up to 1.0 Pa while introducing an Ar gas into the chamber. Next, after the substrate (Pt foil) was heated to a temperature of 400° C., electric power of 500 W was applied to the film formation target to form a dielectric film on the substrate (Pt foil) in a thickness of approximately 200 nm, thereby forming a dielectric layer.

Next, the dielectric layer was subjected to a heat treatment at 900° C. for 60 minutes.

Next, a Pt film was formed on the dielectric layer to form a second electrode layer. Formation of the Pt film was performed by a sputtering method. First, Pt was prepared as a film formation target. Next, the substrate (Pt foil) on which the dielectric layer was formed was provided in the chamber of the film formation device. At this time, a distance between the film formation target and the dielectric layer was set to 85 mm. Next, the inside of the chamber was reduced up to a pressure of 2.0 Pa while introducing an Ar gas into the chamber. Next, after the substrate (Pt foil) was heated to a temperature of 500° C., electric power of 300 W was applied to the film formation target to form a Pt film on the dielectric layer in a thickness of approximately 500 nm so as to form the second electrode layer, thereby preparing the dielectric thin film element.

Methods of measuring the concentration of impurities in the dielectric layer, various kinds of surface roughness, and the dielectric breakdown resistance were similar as in Experimental Example 1. Results are shown in Table 1.

(Experimental Example 4: Sample Numbers 12 to 14)

Ir foil was prepared as a first electrode layer also serving as a substrate. Note that, the Mohs hardness of the first electrode layer was 4 or more and was higher than the Mohs hardness of the first electrode layer in Experimental Example 1. Next, a surface of the Ir foil was ultrasonically cleaned. The surface of the cleaned Ir foil was polished. The surface polishing was performed a plurality of times by using alumina abrasive grains. At the first surface polishing, alumina abrasive grains in which D50 of abrasive grains is 0.5 μm were used. At the second surface polishing, alumina abrasive grains in which D50 of abrasive grains is 0.3 μm were used. At the third surface polishing, alumina abrasive grains in which D50 of abrasive grains is 0.05 μm were used. The surface polishing was performed three times in all samples.

As a surface treatment, in Sample Number 12, sputtering was performed with respect to the surface-polished substrate (Ir foil) by a sputtering method. In Sample Number 13, reverse sputtering was performed with respect to the surface-polished substrate (Ir foil) by a reverse sputtering method. In Sample Number 14, neither the sputtering nor the reverse sputtering was performed.

In the sputtering method, a target formed from the same metal (Ir) as in the substrate (Ir foil) and the surface-polished substrate (Ir foil) were provided in the chamber of the film formation device. The target and the polished surface of the substrate (Ir foil) were set to face each other. At this time, a distance between the target and the substrate (Ir foil) was set to 85 mm. Next, the pressure inside the chamber was reduced up to 2.0 Pa while introducing an Ar gas into the chamber. Next, electric power of 300 W was applied to the target to form a film of Ir on the substrate (Ir foil) in a thickness of approximately 500 nm. Note that, a temperature of the substrate (Ir foil) was set to room temperature.

In the reverse sputtering method, a target formed from Ir and the surface-polished Ir foil were provided in the chamber of the film formation device. At this time, the distance between the target and the substrate (Ir foil) was set to 85 mm. Next, the pressure inside the chamber was reduced up to 2.0 Pa while introducing an Ar gas into the chamber. Next, electric power of 300 W was applied to the substrate (Ir foil) to plasma-etch the substrate (Ir foil) by approximately 5 nm. Note that, a temperature of the substrate (Ir foil) was set to room temperature.

Next, a dielectric film was formed on the substrate (Ir foil), thereby forming a dielectric layer. Formation of the dielectric film was performed by a sputtering method. First, BaTiO₃ was prepared as a film formation target. Next, the film formation target formed from BaTiO₃ and the surface-polished substrate (Ir foil) were provided in the chamber of the film formation device. At this time, a distance between the film formation target and the substrate (Ir foil) was set to 50 mm. Next, the pressure inside the chamber was reduced up to 1.0 Pa while introducing an Ar gas into the chamber. Next, after the substrate (Ir foil) was heated to a temperature of 400° C., electric power of 500 W was applied to the film formation target to form a dielectric film on the substrate (Ir foil) in a thickness of approximately 200 nm, thereby forming a dielectric layer.

Next, the dielectric layer was subjected to a heat treatment at 900° C. for 60 minutes.

Next, an Ir film was formed on the dielectric layer to form a second electrode layer. Formation of the Ir film was performed by a sputtering method. First, Ir was prepared as a film formation target. Next, the substrate (Ir foil) on which the dielectric layer was formed was provided in the chamber of the film formation device. At this time, a distance between the film formation target and the dielectric layer was set to 85 mm. Next, the inside of the chamber was reduced up to a pressure of 2.0 Pa while introducing an Ar gas into the chamber. Next, after the substrate (Ir foil) was heated to a temperature of 500° C., electric power of 300 W was applied to the film formation target to form an Ir film on the dielectric layer in a thickness of approximately 500 nm so as to form the second electrode layer, thereby preparing the dielectric thin film element.

Methods of measuring the concentration of impurities in the dielectric layer, various kinds of surface roughness, and the dielectric breakdown resistance were similar as in Experimental Example 1. Results are shown in Table 1.

(Experimental Example 5: Sample Numbers 15 to 17)

Al foil was prepared as a first electrode layer also serving as a substrate. Note that, the Mohs hardness of the first electrode layer was less than 4, and was lower than the Mohs hardness of the first electrode layer in Experimental Example 1. Next, a surface of the Al foil was ultrasonically cleaned. The surface of the cleaned Al foil was polished. The surface polishing was performed a plurality of times by using alumina abrasive grains. At the first surface polishing, alumina abrasive grains in which D50 of abrasive grains is 0.5 μm were used. At the second surface polishing, alumina abrasive grains in which D50 of abrasive grains is 0.3 μm were used. At the third surface polishing, alumina abrasive grains in which D50 of abrasive grains is 0.05 μm were used. The surface polishing was performed three times in all samples.

As a surface treatment, in Sample Number 15, sputtering was performed with respect to the surface-polished substrate (Al foil) by a sputtering method. In Sample Number 16, reverse sputtering was performed with respect to the surface-polished substrate (Al foil) by a reverse sputtering method. In Sample Number 17, neither the sputtering nor the reverse sputtering was performed.

In the sputtering method, a target formed from the same metal (Al) as in the substrate (Al foil) and the surface-polished substrate (Al foil) were provided in the chamber of the film formation device. The target and the polished surface of the substrate (Al foil) were set to face each other. At this time, a distance between the target and the substrate (Al foil) was set to 70 mm. Next, the pressure inside the chamber was reduced up to 0.45 Pa while introducing an Ar gas into the chamber. Next, electric power of 500 W was applied to the target to form a film of Al on the substrate (Al foil) in a thickness of approximately 500 nm. Note that, a temperature of the substrate (Al foil) was set to room temperature.

In the reverse sputtering method, a target formed from Al and the surface-polished Al foil were provided in the chamber of the film formation device. At this time, the distance between the target and the substrate (Al foil) was set to 70 mm. Next, the pressure inside the chamber was reduced up to 0.45 Pa while introducing an Ar gas into the chamber. Next, electric power of 500 W was applied to the substrate (Al foil) to plasma-etch the substrate (Al foil) by approximately 20 nm. Note that, a temperature of the substrate (Al foil) was set to room temperature.

Next, a dielectric film was formed on the substrate (Al foil), thereby forming a dielectric layer. Formation of the dielectric film was performed by a sputtering method. First, BaTiO₃ was prepared as a film formation target. Next, the film formation target formed from BaTiO₃ and the surface-polished substrate (Al foil) were provided in the chamber of the film formation device. At this time, a distance between the film formation target and the substrate (Al foil) was set to 50 mm. Next, the pressure inside the chamber was reduced up to 1.0 Pa while introducing an Ar gas into the chamber. Next, after the substrate (Al foil) was heated to a temperature of 400° C., electric power of 500 W was applied to the film formation target to form a dielectric film on the substrate (Al foil) in a thickness of approximately 200 nm, thereby forming a dielectric layer.

Next, the dielectric layer was subjected to a heat treatment at 900° C. for 60 minutes.

Next, an Al film was formed on the dielectric layer to form a second electrode layer. Formation of the Al film was performed by a sputtering method. First, Al was prepared as a film formation target. Next, the substrate (Al foil) on which the dielectric layer was formed was provided in the chamber of the film formation device. At this time, a distance between the film formation target and the dielectric layer was set to 70 mm. Next, the inside of the chamber was reduced up to a pressure of 0.45 Pa while introducing an Ar gas into the chamber. Next, after the substrate (Al foil) was heated to a temperature of 500° C., electric power of 500 W was applied to the film formation target to form an Al film on the dielectric layer in a thickness of approximately 500 nm so as to form the second electrode layer, thereby preparing the dielectric thin film element.

Methods of measuring the concentration of impurities in the dielectric layer, various kinds of surface roughness, and the dielectric breakdown resistance were similar as in Experimental Example 1. Results are shown in Table 1.

(Experimental Example 6: Sample Numbers 18 to 20)

An experiment was carried out under the same conditions as in Sample Number 1 of Experimental Example 1 except that Rsk2 was changed by changing sputtering conditions at the time of forming the second electrode layer to conditions shown in Table 1. Results are shown in Table 1.

(Experimental Example 7: Sample Numbers 21 and 22)

An experiment was carried out under the same conditions as in Sample Number 1 of Experimental Example 1 except that an intermediate layer was formed after forming the first electrode layer, and the dielectric film was formed on the intermediate layer to form the dielectric layer.

The intermediate layer was formed by forming a film of SiO₂ on the substrate (Ni foil). Film formation of SiO₂ was performed by a sputtering method. First, SiO₂ was prepared as a film formation target. Next, the film formation target formed from SiO₂ and the surface-polished substrate (Ni foil) were provided in the chamber of the film formation device. At this time, a distance between the film formation target and the substrate (Ni foil) was set to 50 mm. Next, the pressure inside the chamber was reduced up to 1.0 Pa while introducing an Ar gas into the chamber. Next, after the substrate (Ni foil) was heated to a temperature of 400° C., electric power of 500 W was applied to the film formation target to form an intermediate layer in a film shape on the substrate (Ni foil) in a thickness shown in Table 1, thereby forming the intermediate layer. Note that, the reason why the thickness of the intermediate layer in Experimental Examples other than Sample Numbers 21 and 22 in Table 1 is described as “<1” is because an intermediate layer having a thickness of 1 nm or more is not observed between the first electrode layer and the dielectric layer. Since the intermediate layer is not formed in Experimental Examples other than Sample Numbers 21 and 22, an intermediate layer having a thickness of 1 nm or more was not observed.

Next, a dielectric film was formed on the intermediate layer to form a dielectric layer. Formation of the dielectric film was performed by a sputtering method. First, BaTiO₃ was prepared as a film formation target. Next, the film formation target formed from BaTiO₃ and the substrate (Ni foil) on which the intermediate layer was formed were provided in the chamber of the film formation device. At this time, a distance between the film formation target and the intermediate layer was set to 50 mm. Next, the inside of the chamber was reduced up to a pressure of 1.0 Pa while introducing an Ar gas into the chamber. Next, after a temperature of the substrate (Ni foil) was heated to 400° C., electric power of 500 W was applied to the film formation target to form a dielectric film on the intermediate layer in a thickness of approximately 200 nm, thereby forming the dielectric layer.

Methods of measuring the concentration of impurities in the dielectric layer, various kinds of surface roughness, and the dielectric breakdown resistance were similar as in Experimental Example 1. However, “interface between the first electrode layer and the dielectric layer” is rewritten as “interface between the first electrode layer and the intermediate layer”. Results are shown in Table 1.

TABLE 1

| | | | | | | Dielectric | | |
|---|---|---|---|---|---|---|---|---|
| | | | | | Inermediate | layer | Second | |
| | Example/ | First electrode layer | | | layer | Concentration | electrode | |
| Sample | Comparative | | Rz1 | Ra1 | Thickness | of impurities | layer | Electrode |
| No. | Example | Rsk1 | nm | nm | nm | ppm | Rsk2 | material |
| 1 | Example | 5.00 | 50 | 8 | <1 | 8 | 5.00 | Ni |
| 2 | Example | 2.00 | 50 | 8 | <1 | 8 | 5.00 | Ni |
| 3 | Example | 0.75 | 30 | 5 | <1 | 8 | 5.00 | Ni |
| 4 | Comparative | 0.70 | 50 | 8 | <1 | 8 | 5.00 | Ni |
| | Example | | | | | | | |
| 1 | Example | 5.00 | 50 | 8 | <1 | 8 | 5.00 | Ni |
| 5 | Example | 5.00 | 50 | 8 | <1 | 16 | 5.00 | Ni |
| 6 | Example | 5.00 | 50 | 8 | <1 | 24 | 5.00 | Ni |
| 7 | Example | 5.00 | 50 | 8 | <1 | 40 | 5.00 | Ni |
| 9 | Example | 5.00 | 30 | 5 | <1 | 8 | 5.00 | Pt |
| 10 | Example | 0.75 | 30 | 5 | <1 | 8 | 5.00 | Pt |
| 11 | Comparative | 0.70 | 30 | 5 | <1 | 8 | 5.00 | Pt |
| | Example | | | | | | | |
| 12 | Example | 5.00 | 30 | 5 | <1 | 8 | 5.00 | Jr |
| 13 | Example | 0.85 | 30 | 5 | <1 | 8 | 5.00 | Ir |
| 14 | Example | 0.80 | 30 | 5 | <1 | 8 | 5.00 | Ir |
| 15 | Example | 4.00 | 30 | 5 | <1 | 8 | 3.50 | Al |
| 16 | Example | 0.75 | 30 | 5 | <1 | 8 | 3.50 | Al |
| 17 | Comparative | −1.00 | 30 | 5 | <1 | 8 | 3.50 | Al |
| | Example | | | | | | | |
| 1 | Example | 5.00 | 50 | 8 | <1 | 8 | 5.00 | Ni |
| 18 | Example | 5.00 | 50 | 8 | <1 | 8 | 3.50 | Ni |
| 19 | Example | 5.00 | 50 | 8 | <1 | 8 | −0.90 | Ni |
| 20 | Example | 5.00 | 50 | 8 | <1 | 8 | −1.10 | Ni |
| 1 | Example | 5.00 | 50 | 8 | <1 | 8 | 5.00 | Ni |
| 21 | Example | 5.00 | 50 | 8 | 1 | 8 | 5.00 | Ni |
| 22 | Example | 5.00 | 50 | 8 | 5 | 8 | 5.00 | Ni |

| | | | Sputtering condition | | | | | |
|---|---|---|---|---|---|---|---|---|
| | | | when forming second | | | | | |
| | | | electrode layer | | | | | |
| | | Board | Electric | Board | Dielectric breakdown voltage | | | |
| Sample | Third | surface | power | temperature | VBD(+) | | VBD(−) | |
| No. | polishing | treatment | W | ° C. | V | MV/cm | V | MV/cm |
| 1 | Performed | Sputtering | 500 | 500 | 80 | 4.00 | 80 | 4.00 |
| 2 | Performed | Reverse | 500 | 500 | 70 | 3.50 | 80 | 4.00 |
| | | sputtering | | | | | | |
| 3 | Performed | None | 500 | 500 | 60 | 3.00 | 80 | 4.00 |
| 4 | Not- | None | 500 | 500 | 20 | 1.00 | 80 | 4.00 |
| | Performed | | | | | | | |
| 1 | Performed | Sputtering | 500 | 500 | 80 | 4.00 | 80 | 4.00 |
| 5 | Performed | Sputtering | 500 | 500 | 78 | 3.90 | 80 | 4.00 |
| 6 | Performed | Sputtering | 500 | 500 | 75 | 3.75 | 80 | 4.00 |
| 7 | Performed | Sputtering | 500 | 500 | 30 | 1.50 | 80 | 4.00 |
| 9 | Performed | Sputtering | 500 | 500 | 80 | 4.00 | 80 | 4.00 |
| 10 | Performed | Reverse | 500 | 500 | 60 | 3.00 | 80 | 4.00 |
| | | sputtering | | | | | | |
| 11 | Performed | None | — | — | 20 | 1.00 | 80 | 4.00 |
| 12 | Performed | Sputtering | 500 | 500 | 80 | 4.00 | 80 | 4.00 |
| 13 | Performed | Reverse | 500 | 500 | 65 | 3.25 | 80 | 4.00 |
| | | sputtering | | | | | | |
| 14 | Performed | None | — | — | 60 | 3.00 | 80 | 4.00 |
| 15 | Performed | Sputtering | 500 | 500 | 65 | 3.25 | 60 | 3.00 |
| 16 | Performed | Reverse | 500 | 500 | 40 | 2.00 | 60 | 3.00 |
| | | sputtering | | | | | | |
| 17 | Performed | None | 500 | 500 | 15 | 0.75 | 60 | 3.00 |
| 1 | Performed | Sputtering | 500 | 500 | 80 | 4.00 | 80 | 4.00 |
| 18 | Performed | Sputtering | 500 | 300 | 80 | 4.00 | 75 | 3.75 |
| 19 | Performed | Sputtering | 300 | 300 | 80 | 4.00 | 60 | 3.00 |
| 20 | Performed | Sputtering | 200 | 200 | 80 | 4.00 | 30 | 1.50 |
| 1 | Performed | Sputtering | 500 | 500 | 80 | 4.00 | 80 | 4.00 |
| 21 | Performed | Sputtering | 500 | 500 | 80 | 4.00 | 80 | 4.00 |
| 22 | Performed | Sputtering | 500 | 500 | 80 | 4.00 | 80 | 4.00 |

From Table 1, in Examples in which Rsk1 is 0.75 or more and 5.0 or less, the breakdown voltage was sufficiently high. In contrast, in Comparative Examples in which Rsk1 is less than 0.75, the breakdown voltage was not sufficiently high.

### DESCRIPTION OF THE REFERENCE NUMERAL

1 THIN FILM CAPACITOR
11 SUBSTRATE
12 FIRST ELECTRODE LAYER
12a INTERFACE BETWEEN FIRST ELECTRODE LAYER AND DIELECTRIC LAYER
13 DIELECTRIC LAYER
14 SECOND ELECTRODE LAYER
14a INTERFACE BETWEEN SECOND ELECTRODE LAYER AND DIELECTRIC LAYER
21 ROUGHNESS CURVE
31 ROUGHNESS SPECTRUM
32 FIRST SPECTRAL COMPONENT
33 SECOND SPECTRAL COMPONENT
34 THIRD SPECTRAL COMPONENT

What is claimed is:

1. A dielectric thin film element comprising a first electrode layer, a dielectric layer, and a second electrode layer located in this order from a substrate side, wherein
a relationship of 0.75≤Rsk1≤5.0 is satisfied, in which
skewness of a roughness curve of the first electrode layer on the dielectric layer side is set as Rsk1.

2. The dielectric thin film element according to claim 1, wherein
a total amount of C, P, S, and Se in the dielectric layer is less than 25 ppm.

3. The dielectric thin film element according to claim 1, wherein
Mohs hardness of the first electrode layer is 4 or more.

4. The dielectric thin film element according to claim 1, wherein
a relationship of −1.0<Rsk2≤5.0 is satisfied, in which
skewness of a roughness curve of the second electrode layer on the dielectric layer side is set as Rsk2.

5. The dielectric thin film element according to claim 1, wherein
an intermediate layer having a thickness of 1 nm or more is provided between the first electrode layer and the dielectric layer.

6. The dielectric thin film element according to claim 1, wherein
the first electrode layer and the dielectric layer are in contact with each other.

7. The dielectric thin film element according to claim 6, wherein
the dielectric layer and the second electrode layer are in contact with each other.

8. An electronic circuit substrate comprising the dielectric thin film element according to claim 1.

9. An electronic circuit device comprising the dielectric thin film element according to claim 1 and a substrate on which the dielectric thin film element is formed.
